(19) United States
(12) Patent Application Publication
(10) Pub. No.: US 2026/0293445 A1
(43) Pub. Date: Sep. 24, 2026

(54) DISPLAY DEVICE, METHOD OF MANUFACTURING THE SAME AND ELECTRONIC DEVICE INCLUDING THE SAME

(71) Applicant: Samsung Display Co., Ltd., Yongin-Si (KR)

(72) Inventor: Chun Gi YOU, Yongin-si (KR)

(21) Appl. No.: 19/569,307

(22) Filed: Mar. 17, 2026

(30) Foreign Application Priority Data
Mar. 18, 2025 (KR) 10-2025-0034673

(51) Int. Cl. H10K 59/122; H10K 59/12; H10K 59/123; H10K 59/124; H10K 59/32; H10K 102/00

(52) U.S. Cl. CPC H10K 59/122; H10K 59/1201; H10K 59/123; H10K 59/124; H10K 59/32; H10K 2102/351

(57) ABSTRACT

A display device includes a base substrate, transistor structures arranged on the base substrate, pixel electrodes electrically connected to each of the transistor structures on the base substrate, a pixel defining layer, a light-emitting portion on the pixel defining layer and the pixel electrodes, and a counter electrode on the light-emitting portion. The pixel defining layer includes a lower stack filling a space between the pixel electrodes and covering a peripheral portion of the pixel electrodes, and an upper stack including a first insulating pattern, a second insulating pattern, and a third insulating pattern sequentially stacked on the lower stack. A width of the second insulating pattern is smaller than a width of the first insulating pattern and a width of the third insulating pattern, and a difference between a maximum thickness and a minimum thickness of the first insulating pattern is 5 nm or less.

### CROSS-REFERENCE TO RELATED APPLICATION

This application claims priority to Korean Patent Application No. 10-2025-0034673 filed on Mar. 18, 2025 in the Korean Intellectual Property Office (KIPO), the entire disclosure of which is incorporated by reference herein.

### BACKGROUND

### 1. FIELD

Embodiments of the present disclosure relate to a display device, a method of manufacturing the same and electronic device including the same. More particularly, embodiments of the present disclosure relate to a display device including a light-emitting element and a pixel defining layer, a method of manufacturing the display device, and electronic device including the display device.

### 2. Description of the Related Art

In a display device such as an organic light emitting diode (OLED) display device and a liquid crystal display (LCD) device, a display substrate including, e.g., a thin film transistor (TFT) and various wirings may be provided, and a display structure including electrodes and emission layers may be formed on the display substrate.

For example, a pixel electrode connecting the TFT and the display structure, and a pixel defining layer defining pixel regions may be provided. Recently, various constructions of the TFT, the pixel electrode and the pixel defining layer for stable implementation of a high-resolution display device have been researched

### SUMMARY

According to an aspect of the present disclosure, there is provided a display device having improved electrical reliability and operational stability.

According to an aspect of the present disclosure, there is provided a method of manufacturing a display device having improved electrical reliability and operational stability.

According to an aspect of the present disclosure, there is provided an electronic device including a display device with improved electrical reliability and operational stability.

A display device may include a base substrate, transistor structures arranged on the base substrate, pixel electrodes electrically connected to each of the transistor structures on the base substrate, a pixel defining layer, a light-emitting portion on the pixel defining layer and the pixel electrodes, and a counter electrode on the light-emitting portion. The pixel defining layer may include a lower stack filling a space between the pixel electrodes and covering a peripheral portion of the pixel electrodes, and an upper stack including a first insulating pattern, a second insulating pattern, and a third insulating pattern sequentially stacked on the lower stack. A width of the second insulating pattern may be smaller than a width of the first insulating pattern and a width of the third insulating pattern, and a difference between a maximum thickness and a minimum thickness of the first insulating pattern may be 5 nm or less.

In some embodiments, the difference between the maximum thickness and the minimum thickness of the first insulating pattern may be 4 nm or less.

In some embodiments, a thickness of the second insulating pattern may be smaller than a thickness of the first insulating pattern and a thickness of the third insulating pattern.

In some embodiments, the thickness of the first insulating pattern and the thickness of the third insulating pattern may be in a range from 180 Å to 250 Å, and the thickness of the second insulating pattern is in a range from 80 Å to 200 Å.

In some embodiments, the first insulating pattern and the third insulating pattern may include silicon oxide, and the second insulating pattern may include silicon nitride.

In some embodiments, the upper stack may have a groove defined by a top surface of the first insulating pattern, a side surface of the second insulating pattern, and a bottom surface of the third insulating pattern.

In some embodiments, the lower stack may include a stopper layer and a filling pattern on the stopper layer.

In some embodiments, the stopper layer may include silicon nitride, and the filling pattern may include a siloxane-based material or silane-based material.

In some embodiments, a top surface of the stopper layer and a top surface of the filling pattern may be located in the same plane.

In some embodiments, the first insulating pattern and the filling pattern may be an integral member.

In some embodiments, the light-emitting portion may include a first emission layer, a charge generation layer, and a second emission layer sequentially stacked on the pixel electrode and the pixel defining layer.

In some embodiments, the first emission layer and the second emission layer may be blue emission layers.

In some embodiments, each of the pixel electrodes may include a first conductive layer, a metal layer, and a second conductive layer including a transparent conductive oxide which are sequentially stacked from the base substrate.

In some embodiments, the second conductive layer may contact a side surface of the metal layer.

In a method of manufacturing a display device, pixel electrodes may be formed on the base substrate. A first insulating layer, a second insulating layer, and a third insulating layer covering the pixel electrodes may be sequentially formed. The third insulating layer and the second insulating layer may be etched to form a third insulating pattern and a second insulating pattern. A side surface of the second insulating pattern may be etched by a wet etching while suppressing an etched thickness of the first insulating layer to 5 nm or less to form a groove. The first insulating layer may be etched to form a first insulating pattern. A light-emitting portion may be formed on the pixel electrodes. A counter electrode may be formed on the light-emitting portion.

In some embodiments, before sequentially forming the first insulating layer, the second insulating layer and the third insulating layer, a stopper layer covering the pixel electrodes may be formed. A filling layer may be formed on the stopper layer to fill a space between the pixel electrodes. The filling layer may be polished so that a top surface of the stopper layer is exposed.

In some embodiments, the first insulating layer, the second insulating layer and the third insulating layer may be sequentially formed on the stopper layer and the filling layer. The second insulating layer and the stopper layer may be formed of silicon nitride, and the first insulating layer and the third insulating layer may be formed of silicon oxide.

In some embodiments, before forming the light-emitting portion, the filling layer and the stopper layer may be etched to form an opening exposing a top surface of the pixel electrode.

An electronic device may include a display device, a memory, and one or more processors executing data included in the memory to control an operation of the display device. The display device may include a base substrate, transistor structures arranged on the base substrate, pixel electrodes electrically connected to each of the transistor structures on the base substrate, a pixel defining layer, a light-emitting portion on the pixel defining layer and the pixel electrodes, and a counter electrode on the light-emitting portion. The pixel defining layer may include a lower stack filling a space between the pixel electrodes and covering a peripheral portion of the pixel electrodes, and an upper stack including a first insulating pattern, a second insulating pattern, and a third insulating pattern sequentially stacked on the lower stack. A width of the second insulating pattern may be smaller than a width of the first insulating pattern and a width of the third insulating pattern, and a difference between a maximum thickness and a minimum thickness of the first insulating pattern may be 5 nm or less.

In some embodiments, the electronic device may include virtual reality or augmented reality glasses, a smartphone, a tablet personal computer (PC), a laptop, a television, a desk monitor, smart glasses, a head-mounted display, a smart watch, or a vehicle display.

In a display device according to embodiments of the present inventive concepts, a thickness deviation of a lower insulating pattern of a pixel defining layer having an undercut structure may be maintained in a specific range. Accordingly, a short circuit between a charge generation layer and a counter electrode in a light-emitting portion due to a non-uniformity of the lower insulating pattern may be prevented.

Thus, a vertical leakage current in an individual pixel such as a blue pixel may be prevented, and a high luminance/high resolution display device may be implemented.

### BRIEF DESCRIPTION OF THE DRAWINGS

FIG. 1 is a schematic plan view illustrating a display device according to embodiments.

FIG. 2 is a pixel equivalent circuit diagram of a display device according to embodiments.

FIG. 3 is a cross-sectional view illustrating a display device according to embodiments.

FIGS. 4 and 5 are schematic cross-sectional views illustrating a light-emitting device according to embodiments.

FIG. 6 is a schematic partially enlarged cross-sectional view illustrating a pixel defining layer according to some embodiments.

FIG. 7 is a schematic partially enlarged cross-sectional view illustrating a pixel defining layer according to some embodiments.

FIG. 8 is a partially enlarged cross-sectional view schematically illustrating a stacked structure of a pixel defining layer, a light-emitting portion, and a counter electrode according to a comparative example.

FIGS. 9, 10, 11, 12, 13, 14, 15, and 16 are schematic cross-sectional views illustrating a method of manufacturing a display device according to embodiments.

FIG. 17 is an exploded perspective view of a display device according to embodiments.

FIG. 18 is a block diagram of an electronic device in accordance with an embodiment.

FIG. 19 is a schematic diagram of electronic devices in accordance with various embodiments.

### DETAILED DESCRIPTION OF THE EMBODIMENTS

Hereinafter, embodiments of the inventive concept will be described in more detail with reference to the attached drawings. The same reference numerals can be used for indicating the same elements in the drawings, and repeated descriptions of the same elements can be omitted. Embodiments disclosed in the attached drawings are exemplary, and is to be understood to include all modifications, equivalents and substitutes included in the spirit and technical scope of the inventive concept.

The terms "on", "connected", "coupled," etc., used herein refers to a direct placement/connection/combination, and also refers to a case where another element is interposed two different elements.

The terms such as "first", "second", "below", "under", "above," "on," etc., are used in a relative sense to distinguish different elements or positions, and do not specify an absolute position or an absolute order.

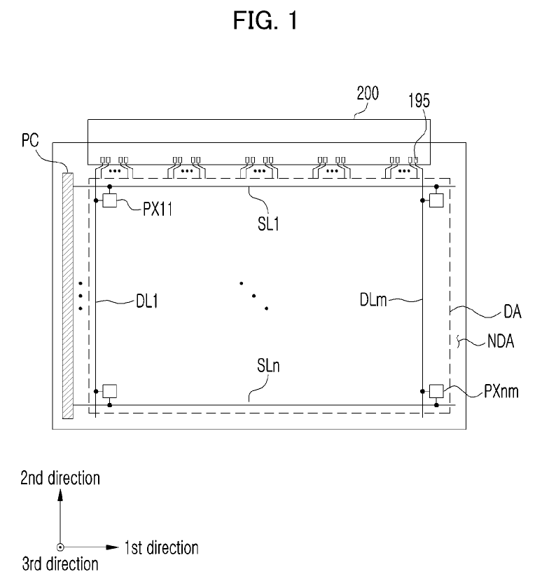

FIG. 1 is a schematic plan view illustrating a display device according to embodiments.

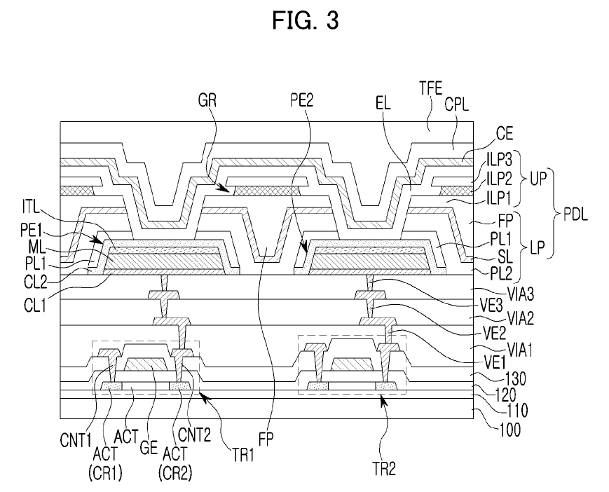

In FIG. 1, a first direction and a second direction may refer to two directions parallel to a top surface of a base substrate 100 (see FIG. 3) and intersecting each other. For example, the first direction and the second direction may be orthogonal to each other.

For example, the first direction may correspond to an X-direction (e.g., a row direction or a width direction) of the display device, and the second direction may correspond to a Y-direction (a column direction or a length direction) of the display device.

The third direction may be perpendicular to the first direction and the second direction. The third direction may correspond to a Z-direction (a thickness direction) of the display device.

In the accompanying drawings, the above definition of the directions may be equally applied.

Referring to FIG. 1, the display device may include a display area DA and a non-display area NDA. The display area DA may provide a surface on which an image of the display device is substantially displayed and a user's touch/command is input. The non-display area NDA may substantially correspond to a bezel area or a peripheral area of the display device. In an embodiment, the display area DA may be substantially surrounded by the non-display area NDA.

The base substrate 100 (see FIG. 3 for example) may also be divided into the display area DA and the non-display area NDA. A plurality of pixels PX11 to PXnm may be arranged on the display area DA of the base substrate 100.

In example embodiments, a pixel circuit including scan lines SL1 to SLn (or gate lines) forming first to n^{th} rows, and data lines DL1 to DLm forming first to m^{th} columns may be arranged on the base substrate 100 of the display device. Each of the pixels PX11 to PXnm may be connected to a scan line of a corresponding row among a plurality of scan lines SL1 to SLn and a data line of a corresponding column among a plurality of data lines DL1 to DLm.

Each of the pixels PX11 to PXnm may further include a pixel circuit including a transistor and a light-emitting element as described below. Although not illustrated in detail in FIG. 1, the pixel circuit may further include wirings such as a power line, a ground line, etc.

FIG. 1 illustrates that the data lines DL1 to DLm extend in the second direction and the scan lines SL1 to SLn extend in the first direction, but the construction of the data lines and the gate lines is not limited to that illustrated in FIG. 1. In FIG. 1, a shape of each pixel PX11 to PXnm is illustrated as a square for convenience of illustration, but the shape of each pixel is not limited to that illustrated in FIG. 1.

A peripheral circuit PC may be disposed in the non-display area NDA corresponding to a peripheral area of the display area DA. For example, the peripheral circuit PC may include a gate driving circuit. The gate driving circuit may be integrated into a display panel DP (see FIG. 17 for example) by an oxide semiconductor gate (OSG) driver circuit process, an amorphous silicon gate (OSG) driver circuit process, or a polysilicon gate (PSG) driver circuit process.

The peripheral circuit PC may further include a data driver, a gate driver, a light-emitting driver, a power voltage generator, a timing controller, or the like.

The display device may further include a printed circuit board 200. Pads 195 of the pixel circuit may be assembled at one end portion of the non-display area NDA. The printed circuit board 200 may be electrically connected to the pixel circuit through the pads 195. For example, the printed circuit board 200 may be electrically connected to the pads 195 by a heat-compression process using a conductive intermediate structure such as an anisotropic conductive film (ACF).

An integrated circuit (IC) such as a data driving circuit may be disposed on the printed circuit board 200. In some embodiments, an integrated circuit (IC) chip in the form of a chip-on-film (COF) may be mounted on the printed circuit board 200.

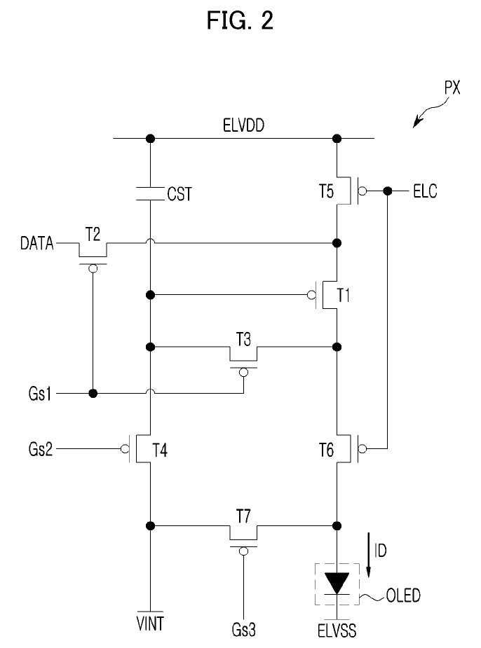

FIG. 2 is a pixel equivalent circuit diagram of a display device according to embodiments.

Referring to FIG. 2, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal and a second terminal. The gate terminal may be connected to the storage capacitor CST. The first terminal may be connected to the second transistor T2. The second terminal may be connected to the sixth transistor T6. The first transistor T1 may generate a driving current ID based on a voltage difference between the gate terminal and the first terminal. For example, the first transistor T1 may be referred to as a driving transistor.

The second transistor T2 may include a gate terminal, a first terminal and a second terminal. The gate terminal of the second transistor T2 may receive a first gate signal Gs1. The second transistor T2 may be turned on or turned off in response to the first gate signal Gs1. The first terminal of the second transistor T2 may receive a data voltage DATA. The second transistor T2 may provide the data voltage DATA to the first terminal of the first transistor T1 in response to the first gate signal Gs1. For example, the second transistor T2 may be referred to as a switching transistor.

The third transistor T3 may include a gate terminal, a first terminal and a second terminal. The gate terminal may receive the first gate signal Gs1. The first terminal may be connected to the gate terminal of the first transistor T1. The second terminal may be connected to the second terminal of the first transistor T1. The third transistor T3 may compensate for a threshold voltage of the first transistor T1. For example, the third transistor T3 may serve as a compensation transistor.

The fourth transistor T4 may include a gate terminal, a first terminal and a second terminal. The gate terminal may receive a second gate signal Gs2. The first terminal may be connected to the gate terminal of the first transistor T1. The second terminal may receive an initialization voltage VINT. The fourth transistor T4 may initialize the gate terminal of the first transistor T1.

The fifth transistor T5 may include a gate terminal, a first terminal and a second terminal. The gate terminal may receive an emission control signal ELC. The first terminal may receive a high-power supply voltage ELVDD. The second terminal may be connected to the first transistor T1.

The sixth transistor T6 may include a gate terminal, a first terminal and a second terminal. The gate terminal may receive the emission control signal ELC. The first terminal may be connected to the first transistor T1. The second terminal may be connected to an organic light-emitting diode OLED. The sixth transistor T6 may transfer the driving current ID to the organic light emitting diode OLED in response to the emission control signal ELC.

The seventh transistor T7 may include a gate terminal, a first terminal and a second terminal. The gate terminal may receive a third gate signal Gs3. The first terminal may be connected to the organic light-emitting diode OLED. The second terminal may receive the initialization voltage VINT. The seventh transistor T7 may initialize the organic light-emitting diode OLED.

The storage capacitor CST may include a first terminal and a second terminal. The first terminal may receive the high-power supply voltage ELVDD. The second terminal may be connected to the gate terminal of the first transistor T1.

The organic light-emitting diode OLED may include a first terminal and a second terminal. The first terminal may be connected to the sixth transistor T6. The second terminal may receive a low-power supply voltage ELVSS. The organic light-emitting diode OLED may emit a light based on the driving current ID.

In FIG. 2, a structure of 7T1C including seven thin film transistors and one storage capacitor CST in each pixel PX is illustrated, but the pixel structure of the display device disclosed herein is not limited thereto.

For example, each pixel PX may include two or more transistors, and may have a structure such as 2T1C, 5T1C, 6T1C, 5T2C, 6T2C, or the like.

FIG. 3 is a schematic cross-sectional view illustrating a display device according to embodiments.

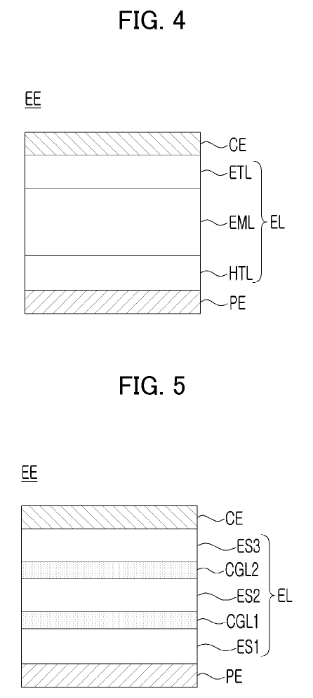

Referring to FIG. 3, the display device may include the base substrate 100, a pixel circuit including transistor structures TR1 and TR2, and a light-emitting element EE (see FIGS. 4 and 5).

For convenience of descriptions, FIG. 3 illustrates structures corresponding to only two neighboring pixels.

The base substrate 100 may serve as a back-plane substrate of a display device. A glass substrate, a ceramic substrate or a plastic substrate may be used as the base substrate 100. In some embodiments, the base substrate 100 may include a polymer material having transparency and flexibility. In this case, the base substrate 100 may be used in a transparent flexible display device.

For example, the base substrate 100 may include a polymer material such as polyimide, polysiloxane, an epoxy resin, an acrylic resin, polyester, or the like. In an embodiment, the base substrate 100 may include polyimide.

In an embodiment, the base substrate 100 may be a glass substrate. In an embodiment, the base substrate 100 may be a silicon substrate prepared from a silicon wafer.

A buffer layer 110 may be formed on a top surface of the base substrate 100. Moisture penetrating through the base substrate 100 may be blocked by the buffer layer 110, and diffusion of impurities between the base substrate 100 and structures formed on the base substrate 100 may also be blocked by the buffer layer 110. The buffer layer 110 may be formed entirely over the display area DA and the non-display area NDA of the base substrate 100, and may entirely cover the top surface of the base substrate 100.

The buffer layer 110 may include, e.g., an inorganic insulating material such as silicon oxide, silicon nitride, silicon oxynitride, or the like. These may be used alone or in a combination thereof.

In some embodiments, the buffer layer 110 may have a stacked structure including a silicon oxide layer and a silicon nitride layer. The buffer layer 110 may be formed by a deposition process such as a chemical vapor deposition (CVD) process, a sputtering process, an atomic layer deposition (ALD) process, or the like, to include the above-mentioned inorganic insulating material.

In some embodiments, the buffer layer 110 may include an organic layer, and may have a multi-layered structure of an organic layer and an inorganic layer.

The pixel circuit may include wirings including the scan lines and the data lines described with reference to FIG. 1, and transistor structures TR1 and TR2 electrically interacting with the wirings. Each of the transistor structures TR1 and TR2 may be electrically connected to the light-emitting element EE.

The transistor structures TR1 and TR3 may each include an active layer ACT, a gate insulation layer 120, and a gate electrode GE. The transistor structure TR1 and TR2 may further include contact electrodes CNT1 and CNT2.

The active layer ACT may be disposed on the buffer layer 110, and may be patterned through a photo-lithography process to be repeatedly/regularly arranged at each pixel. The active layer ACT may include a silicon compound such as polysilicon or amorphous silicon. A p-type dopant or an n-type dopant may be doped in a partial region of the active layer ACT, and the active layer ACT may include a source region, a drain region, and a channel region.

The active layer ACT may include an oxide semiconductor such as indium gallium zinc oxide (IGZO), zinc tin oxide (ZTO), or indium tin zinc oxide (ITZO).

The gate insulation layer 120 may be formed on an active layer ACT, and the gate electrode GE may be stacked on the gate insulation layer 120. As illustrated in FIG. 3, the gate insulation layer 120 may be included commonly throughout the first and second transistor structures TR1 and TR2, or pixels of different colors.

In an embodiment, the gate insulation layer 120 may partially cover each active layer ACT, and may be formed in a pattern shape independently at each of the first and second transistor structures TR1 and TR2.

The gate electrode GE may overlap the channel region of the active layer ACT in the third direction. A scan signal may be transmitted from the scan line through the gate electrode GE.

The gate insulation layer 120 may be formed by the above-mentioned deposition process to include an inorganic insulating material such as silicon oxide, silicon nitride, silicon oxynitride, or a metal oxide.

In some embodiments, a p-type dopant or an n-type dopant may be injected into the active layer ACT by an ion implantation process using the gate electrode GE as an ion implantation mask. Accordingly, a first contact region CR1 and a second contact region CR2 may be formed on one side portion and the other side portion of the active layer ACT, respectively. The first contact region CR1 and the second contact region CR2 may correspond to a source region and a drain region, respectively.

A portion of the active layer ACT overlapping the gate electrode GE in a vertical direction (the third direction) and disposed between the first contact region CR1 and the second contact region CR2 may be defined as the channel region.

In some embodiments, the gate insulation layer 120 may be formed in a pattern covering the channel region through an etching process using the gate electrode GE as an etching mask. When the active layer ACT includes the oxide semiconductor, hydrogen (H) included in an insulating interlayer 130 may be diffused or transferred to the active layer ACT during the formation of the insulating interlayer 130. Accordingly, a carrier concentration may be increased by hydrogen to form the contact regions CR1 and CR2 at the side portions of the active layer ACT.

The insulating interlayer 130 covering the gate electrode GE and the gate insulation layer 120 may be formed on the active layer ACT. The insulating interlayer 130 may be formed by the above-mentioned deposition process to include an inorganic insulating material such as silicon oxide, silicon nitride, silicon oxynitride, or the like. The insulating interlayer 130 may be formed in a single-layered structure or a multi-layered structure including different materials.

The contact electrodes CNT1 and CNT2 which may be in contact with or electrically connected to the active layer ACT may be formed on the insulating interlayer 130.

The first contact electrode CNT1 may be connected to or in contact with the first contact region CR1 of the active layer ACT, and the second contact electrode CNT2 may be connected to or in contact with the second contact region CR2 of the active layer ACT. In some embodiments, the first contact electrode CNT1 and the second contact electrode CNT2 may serve as a source electrode and a drain electrode, respectively.

According to embodiments, the insulating interlayer 130 may be partially etched to form contact holes. For example, contact holes exposing each of the first contact region CR1 and the second contact region CR2 may be formed. The contact holes may also extend through the gate insulation layer 120.

A metal layer filling the contact holes may be formed on the insulating interlayer 130, and then may be partially etched to form the first contact electrode CNT1 and the second contact electrode CNT2. For example, a data signal may be transferred from the data line through the first contact electrode CNT1.

The gate electrode GE and the contact electrodes CNT1 and CNT2 may include a metal such as Ag, Mg, Al, W, Cu, Ni, Cr, Mo, Ti, Pt, Ta, Nd, Sc, an alloy thereof, or a nitride thereof. The gate electrode GE and the contact electrodes CNT1 and CNT2 may be formed by a deposition process such as a sputtering process.

The gate electrode GE and the contact electrodes CNT1 and CNT2 may be formed in a multi-layered structure (e.g., a Ti layer-an Al layer-a Ti layer).

As described above, the first and second transistor structures TR1 and TR2 may be formed to form a thin film transistor (TFT)-array. The first transistor structure TR1 and the second transistor structure TR2 may be transistor structures included in pixels of different colors.

In a non-limiting example, at least one of the first transistor structure TR1 and the second transistor structure TR2 may be a transistor structure corresponding to a blue pixel. For example, the first transistor structure TR1 may be a transistor structure corresponding to a blue pixel, and the second transistor structure TR2 may be a transistor structure corresponding to a green pixel. In this case, a third transistor structure corresponding to a red pixel may be arranged together with the first transistor structure TR1 and the second transistor structure TR2.

In an embodiment, the first transistor structure TR1 and the second transistor structure TR2 may be transistor structures included in pixels (e.g., blue pixels) of the same color.

A first via insulation layer VIA1 covering the contact electrodes CNT1 and CNT2 may be formed on the insulating interlayer 130. The first via insulation layer VIA1 may be substantially provided as a planarization layer of the TFT-array.

The first via insulation layer VIA1 may be partially etched to form a first via hole exposing a top surface of the contact electrode (e.g., the second contact electrode CNT2). An electrode layer filling the first via hole may be formed on a top surface of the first via insulation layer VIA1, and then may be partially etched to form a first via electrode VE1.

A second via insulation layer VIA2 covering the first via electrode VE1 may be formed on the first via insulation layer VIA1. The second via insulation layer VIA2 may be partially etched to form a second via hole exposing a top surface of the first via electrode VE1. An electrode layer filling the second via hole may be formed on a top surface of the second via insulation layer VIA2, and then may be partially etched to form the second via electrode VE2.

A third via insulation layer VIA3 covering the second via electrode VE2 may be formed on the second via insulation layer VIA2. The third via insulation layer VIA3 may be partially etched to form a third via hole exposing a top surface of the second via electrode VE2. An electrode layer may be filled in the third via hole to form a third via electrode VE3 filling the third via hole. The third via electrode VE3 may also be formed on a top surface of the third via insulation layer VIA3.

The first to third via insulation layers VIA1, VIA2 and VIA3 may be formed as organic insulation layers. For example, the first to third via insulating layers VIA1, VIA2 and VIA3 may include an organic polymer material such as polyimide, an epoxy resin, an acrylic resin, polyester, a siloxane resin, benzocyclobutene (BCB), or the like. For example, the first to third via insulation layers VIA1, VIA2 and VIA3 may be formed by a coating process such as a spin coating process.

The electrode layers for forming the via electrodes VE1, VE2 and VE3 may include a metal such as Ag, Mg, Al, W, Cu, Ni, Cr, Mo, Ti, Pt, Ta, Nd, Sc, an alloy thereof, or a nitride thereof. The electrode layers may be formed by a deposition process such as a sputtering process.

Each of first and second pixel electrodes PE1 and PE2 may be in contact with or electrically connected to the third via electrode VE3 on the third via insulation layer VIA3. Accordingly, the first and second pixel electrodes PE1 and PE2 may be electrically connected to the contact electrode (e.g., the second contact electrode CNT2) of the first and second transistor structures TR1 and TR2, respectively, through the via electrodes VE1, VE2 and VE3.

FIG. 3 illustrates the via insulation layer of a triple-layered structure and the via electrode of a triple-layered structure, but the construction of the display device of the present disclosure is not limited to that illustrated in FIG. 3. For example, the via insulation layer/the via electrode may have a single-layered structure or a double-layered structure, or four or more via insulation layers/via electrodes may be included.

The first and second pixel electrodes PE1 and PE2 may be provided as an anode of the light-emitting element EE of a corresponding pixel. According to embodiments, the pixel electrode PE1 and PE2 may serve as a reflective electrode including a metal layer ML.

Each of the pixel electrodes PE1 and PE2 may further include a conductive layer. According to embodiments, each of the pixel electrodes PE1 and PE2 may include a multi-layered structure including a first conductive layer CL1, a metal layer ML, and a second conductive layer CL2 sequentially stacked from the top surface of the third via insulation layer VIA3.

The first conductive layer CL1 may include a metal different from that of the metal layer ML. According to embodiments, the first conductive layer CL1 may include a metal having higher chemical stability and adhesion properties than a metal included in the metal layer ML. In some embodiments, the first conductive layer CL1 may include titanium (Ti) or tantalum (Ta). For example, the first conductive layer CL1 may include titanium (Ti).

The metal layer ML may be substantially provided as a reflective layer of the pixel electrode PE. According to embodiments, the metal layer ML may include silver (Ag) and/or aluminum (Al).

In some embodiments, the first conductive layer CL1 may include a transparent conductive oxide such as indium tin oxide (ITO), indium zinc oxide (IZO), zinc oxide (ZnO), indium tin oxide (ITZO), or the like.

The second conductive layer CL2 may include a transparent conductive oxide. For example, the second conductive layer CL2 may include a transparent conductive oxide such as ITO, IZO, ZnO, ITZO, or the like. In some embodiments, the second conductive layer CL2 may be formed of ITO.

According to embodiments, an intermediate insulating layer ITL may be included between the second conductive layer CL2 and the metal layer ML. The intermediate insulating layer ITL may be included as a protective layer or a capping layer of the metal layer ML when forming the second conductive layer CL2. In some embodiments, the intermediate insulating layer ITL may include an insulating oxide such as silicon oxide.

The second conductive layer CL2 may entirely cover a stacked structure of the first conductive layer CL1, the metal layer ML and the intermediate insulating layer ITL on the third via insulation layer VIA3. Accordingly, the second conductive layer CL2 may be in contact with a side surface of the metal layer ML to provide a side contact structure. Thus, an aperture ratio or an effective area of the pixel region may be increased through the second conductive layer CL2. The second conductive layer CL2 may also be in contact with a side surface of the first conductive layer CL1.

A thickness of the metal layer ML may be greater than each thickness of the first and second conductive layers CL1 and CL2. Accordingly, low resistance and high reflection properties of the pixel electrodes PE1 and PE2 may be effectively implemented.

A pixel defining layer PDL that may substantially define a pixel region or a light-emitting region may be formed on the pixel electrodes PE1 and PE2. The pixel defining layer PDL may be formed to at least partially expose top surfaces (e.g., a top surface of the second conductive layer CL2) of the pixel electrodes PE1 and PE2. The pixel defining layer PDL may cover peripheral portions of the pixel electrodes PE1 and PE2.

According to embodiments, the pixel defining layer PDL may include a lower stack LP and an upper stack UP. Each of the lower stack LP and the upper stack UP may include a plurality of insulating layers.

The lower stack LP may cover the peripheral portions of the pixel electrodes PE1 and PE2, and may fill a space between the neighboring pixel electrodes PE1 and PE2. The lower stack LP may include a first protective layer PL1, a second protective layer PL2, and a stopper layer SL, which are sequentially stacked from the top surface of the second conductive layer CL2.

The first protective layer PL1 and the second protective layer PL2 may include an insulating inorganic oxide such as silicon oxide. In some embodiments, the first protective layer PL1 and the second protective layer PL2 may be substantially merged into a single protective layer.

The stopper layer SL may include an insulating inorganic nitride such as silicon nitride. As described later, the stopper layer SL may be provided as a polishing stopper layer.

The first protective layer PL1, the second protective layer PL2, and the stopper layer SL may be conformally formed along a profile of surfaces of neighboring pixel electrodes PE1 and PE2 and the third via insulation layer VIA3 between the neighboring pixel electrodes PE1 and PE2. Accordingly, each of the first protective layer PL1, the second protective layer PL2, and the stopper layer SL may have a stepped structure, and a trench-shaped space may be formed in the stopper layer SL.

The lower stack LP may include a filling pattern FP. According to embodiments, the filling pattern FP may include an organic insulating material. In some embodiments, the filling pattern FP may include a siloxane-based or a silane-based material. For example, the filling pattern FP may include an organosiloxane material such as tetraethyl orthosilicate (TEOS) or an organosilane-based material.

The filling pattern FP may be provided as a planarization layer of the lower stack LP. According to embodiments, a top surface of the stopper layer SL and a top surface of the filling pattern FP may be located substantially in the same plane. For example, the top surface of the stopper layer SL and the top surface of the filling pattern FP may form substantially a single plane.

The upper stack UP may include a first insulating pattern ILP1, a second insulating pattern ILP2, and a third insulating pattern ILP3 sequentially stacked from a top surface of the lower stacked body LP.

Each of the first insulating pattern ILP1 and the third insulating pattern ILP3 may include an inorganic insulating oxide such as silicon oxide. The second insulating pattern ILP2 may include an inorganic insulating nitride such as silicon nitride.

In some embodiments, a width of the second insulating pattern ILP2 may be less than a width of each of the first insulating pattern ILP1 and the third insulating pattern ILP3. For example, the upper stack UP may include a groove GR. The groove GR may be defined by a top surface of the first insulating pattern ILP1, a side surface of the second insulating pattern ILP2, and a bottom surface of the third insulating pattern ILP3.

In some embodiments, the filling pattern FP and the first insulating pattern ILP1 may be merged into a substantially integral member.

A light-emitting portion EL may be formed on top surfaces of the pixel electrodes PE1 and PE2 exposed by the pixel defining layer PDL and a surface of the pixel defining layer PDL. The light-emitting portion EL may include an organic light-emitting layer that may be independently patterned for each of a red pixel region, a green pixel region, and a blue pixel region to generate lights of different colors for each pixel.

In an embodiment, the light-emitting portion EL may fill the groove GR or may conformally extend along a surface of the groove GR. In an embodiment, the light-emitting portion EL may discontinuously extend by the groove GR.

Although not illustrated in detail in FIG. 3, for example, a hole transport layer HTL or a hole injection layer among layers included in the light-emitting portion EL may be at least partially cut or discontinued in the groove GR. Accordingly, a side leakage current between adjacent pixel regions may be prevented or reduced.

In an embodiment, the light-emitting portion EL may continuously and commonly extend across a plurality of pixels. In this case, the light-emitting portion EL may include a white light-emitting layer or a blue light-emitting layer. In an embodiment, the light-emitting portion EL may include a plurality of emission layers corresponding to different colors or the same colors, and may include a stack having a tandem structure.

The light-emitting element EE including the light-emitting portion EL will be described in more detail with reference to FIGS. 4 and 5.

A counter electrode CE may be disposed on the light-emitting portion EL. The counter electrode CE may be a common electrode that may be continuously and commonly provided in a plurality of pixel regions.

The counter electrode CE may be provided as an electron injection electrode or a cathode. The counter electrode CE may include a metal, an alloy, an electrically conductive compound, or the like, having a low work function.

For example, the counter electrode CE may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. These may be used alone or in a combination of two or more therefrom.

The counter electrode CE may be formed as a transmissive electrode, a translucent electrode, or a reflective electrode. The counter electrode CE may have a single-layered structure or a multi-layered structure.

The counter electrode CE may be formed by a deposition process such as a sputtering process using a target that may include the above-described conductive material.

The light-emitting element EE may be defined by the pixel electrode PE, the light-emitting portion EL, and the counter electrode CE as described above. The light-emitting element EE may be provided as an organic light-emitting diode (OLED) element.

A capping layer CPL may be formed on the counter electrode CE. The capping layer CPL may be formed as a continuous common layer covering a plurality of pixel regions or the light-emitting elements EE.

The capping layer CPL may be formed as an organic capping layer including an organic material, an inorganic capping layer including an inorganic material, or an organic-inorganic hybrid capping layer including both organic and inorganic materials.

For example, the capping layer CPL may include a carbocyclic compound, a heterocyclic compound, an amine group-containing compound, a phosphine derivative, a phthalocyanine derivative, a naphthalocyanine derivative, an alkali metal complex, an alkaline earth metal complex, or the like. These may be used alone or in a combination of two or more therefrom.

An encapsulation layer TFE may be formed on the capping layer CPL. The encapsulation layer TFE may be disposed on the pixel defining layer PDL and the light-emitting elements EE to protect the light-emitting elements EE from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)), or any combination thereof; or a combination of the inorganic and organic layers.

The encapsulation layer TFE may be formed in a single-layered structure or a multi-layered structure. In some embodiments, the encapsulation layer TFE may have a sequential stacked structure of a first inorganic layer, an organic layer, and a second inorganic layer.

In some embodiments, a color control layer overlapping the light-emitting portion EL may be disposed on the encapsulation layer TFE. The color control layer may include a color conversion layer including quantum dots and/or a color filter.

In some embodiments, a sensor layer such as a touch sensor layer and/or an optical functional layer such as a polarizing plate, an anti-reflection layer, an antistatic layer, or the like, may be disposed on the encapsulation layer TFE.

FIGS. 4 and 5 are schematic cross-sectional views illustrating the light-emitting element EE according to embodiments.

Referring to FIG. 4, the light-emitting element EE may include the pixel electrode PE, the counter electrode CE, and the light-emitting portion EL disposed between the pixel electrode PE and the counter electrode CE as described above.

The light-emitting portion EL may include the hole transport layer HTL, an emission layer EML and an electron transport layer ETL. According to embodiments, the hole transport layer HTL, the emission layer EML, the electron transport layer ETL and the counter electrode CE may be sequentially stacked from the top surface of the pixel electrode PE.

The emission layer EML may include an organic light-emitting material having red, green or blue emission properties. For example, the emission layer EML may include a fluorescent host and/or a host for a phosphorescent device, and may further include a fluorescent dopant, a phosphorescent dopant, and/or a thermally activated delayed fluorescence (TADF) dopant.

For example, the hole transport layer HTL may include a hole transporting material such as m-MTDATA (4,4',4"-[tris(3-methylphenyl)phenylamino] triphenylamine), TDATA (4,4'4"-tris(N,N-diphenylamino)triphenylamine), 2-TNATA (4,4',4"-tris[N(2-naphthyl)-N-phenylamino]-triphenylamine), NPB (N,N'-di(naphthalene-l-yl)-N,N'-diphenyl-benzidine), TPD (N,N'-bis(3-methylphenyl)-N,N'-diphenyl-[1,1'-biphenyl]-4,4'-diamine), TCTA (4,4',4"-tris(N-carbazolyl)triphenylamine), PEDOT/PSS (poly(3,4-ethylenedioxythiophene)/poly(4-styrenesulfonate)), or the like.

For example, the electron transport layer ETL may include an electron transporting material such as Alq₃(tris(8-hydroxyquinolinato)aluminum), TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1'-biphenyl-4-olato)aluminum), or the like.

In some embodiments, the hole transport layer HTL and the electron transport layer ETL may be formed as a common layer continuously extending over a plurality of pixel regions.

In some embodiments, a hole injection layer may be further disposed between the pixel electrode PE and the hole transport layer HTL. An electron injection layer may be further disposed between the counter electrode CE and the electron transport layer ETL.

The layers included in the light-emitting portion EL may be formed by a thermal deposition, an evaporation deposition, a vacuum deposition, a spin coating, an inkjet printing, a laser printing, a casting, a laser thermal transfer, or the like.

Referring to FIG. 5, the light-emitting portion EL may include a plurality of the light-emitting structures. Each of the light-emitting structures may include a hole transport layer, an emission layer and an electron transport layer. According to embodiments, the light-emitting element EE of FIG. 5 may be a light-emitting element having a tandem structure.

In an embodiment, the light-emitting structures may include a first light-emitting structure ES1, a second light-emitting structure ES2 and a third light-emitting structure ES3.

Charge generation layers CGL1 and CGL2 may be disposed between the neighboring light-emitting structures. The charge generation layers CGL1 and CGL2 may include a p-type charge generation layer and/or an n-type charge generation layer. The charge generation layers CGL1 and CGL2 may include a first charge generation layer CGL1 between the first light-emitting structure ES1 and the second light-emitting structure ES2, and a second charge generation layer CGL2 between the second light-emitting structure ES2 and the third light-emitting structure ES3.

According to embodiments, the first light-emitting structure ES1, the first charge generation layer CGL1, the second light-emitting structure ES2, the second charge generation layer CGL2, the third light-emitting structure ES3 and the counter electrode CE may be sequentially stacked from the top surface of the pixel electrode PE.

FIG. 5 illustrates an example of the light-emitting element EE having a triple-layer tandem structure, but the light-emitting elements EE may have a tandem structure of double-layered or a tandem structure including four or more layers.

In some embodiments, a light-emitting element of a tandem structure in which a double-layered blue emission layer is stacked with one charge generation layer interposed therebetween may be disposed in the blue pixel region.

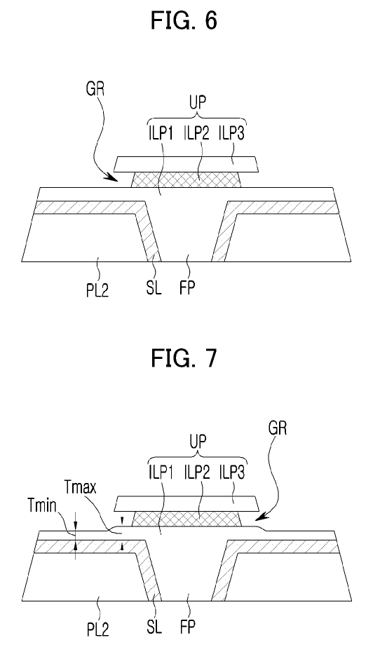

FIG. 6 is a schematic partially enlarged cross-sectional view illustrating a pixel defining layer according to some embodiments.

Referring to FIG. 6, as described with reference to FIG. 3, the upper stack UP of the pixel defining layer PDL may have a stacked structure of the first insulating pattern ILP1, the second insulating pattern ILP2, and a third insulating pattern ILP3.

In some embodiments, a top surface of the first insulating pattern ILP1 may have a flat surface substantially without a concave portion, a recess, and/or a stepped portion. According to embodiments, a thickness of the first insulating pattern ILP1 may be substantially uniform on an uppermost surface of the stopper layer SL.

In some embodiments, a thickness of the second insulating pattern ILP2 may be smaller than each thickness of the first insulating pattern ILP1 (the thickness on the uppermost surface of the stopper layer SL) and a thickness of the third insulating pattern ILP3. Accordingly, as described later, an etching amount for forming the second insulating pattern ILP2 may be reduced, so that a thickness reduction and step/recess formation due to etching damages of the first insulating pattern ILP1 may be prevented.

For example, the thickness of each of the first insulating pattern ILP1 and the third insulating pattern ILP3 may be in a range from about 180 Å to about 250 Å, from about 190 Å to about 240 Å, or from about 200 Å to about 230 Å. The thickness of the second insulating pattern ILP2 may be in a range from about 80 Å to about 200 Å, or from about 90 Å to about 150 Å.

FIG. 7 is a schematic partially enlarged cross-sectional view illustrating a pixel defining layer according to some embodiments.

Referring to FIG. 7, a maximum thickness of the first insulating pattern ILP1 may be represented by Tmax, and a minimum thickness of the first insulating pattern ILP1 may be represented by Tmin. According to embodiments, a difference between the maximum thickness Tmax and the minimum thickness Tmin of the first insulating pattern ILP1 may be 5 nm or less. In an embodiment, the difference between the maximum thickness Tmax and the minimum thickness Tmin of the first insulating pattern ILP1 may be 4 nm or less, or 3.5 nm or less.

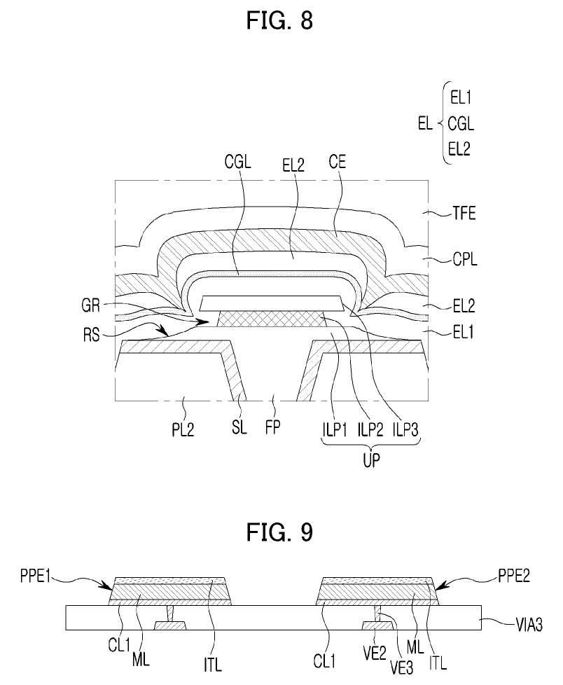

FIG. 8 is a partially enlarged cross-sectional view schematically illustrating a stacked structure of a pixel defining layer, a light-emitting portion, and a counter electrode according to a comparative example.

According to the comparative example of FIG. 8, an upper portion or an end portion of the first insulating pattern ILP1 may be damaged or removed according to an insufficient etching selectivity in an etching process (e.g., a dry etching process) for forming the second insulating pattern ILP2 and the groove GR.

Accordingly, a recess RS having a stepped portion or a decreased height may be formed in the first insulating pattern ILP1. In this case, the light-emitting portion EL and the counter electrode CE formed along the surface of the pixel defining layer PDL may also include concave portions due to the recess RS.

For example, the light-emitting portion EL may have a tandem structure including a first light-emitting portion EL1 and a second light-emitting portion EL2 stacked with a charge generation layer CGL interposed therebetween. In this case, the concave portions may be generated in the charge generation layer CGL, the second light-emitting portion EL2, and the counter electrode CE, and a short circuit may occur between the charge generation layer CGL and the counter electrode CE.

For example, if the first light-emitting portion EL1 and the second light-emitting portion EL2 each includes a blue emission layer, a vertical leakage current may occur due to the short circuit between the charge generation layer CGL and the counter electrode CE in a blue pixel region.

Further, the concave portions may also be generated in the capping layer CPL and the encapsulation layer TFE, resulting in a seam portion in the encapsulation layer TFE to reduce a flatness of the encapsulation layer TFE.

However, according to above-described embodiments of the present inventive concepts, a substantially flat upper surface may be maintained by suppressing a thickness deviation of the first insulating pattern ILP1. Accordingly, flatness of layers included in the light-emitting portion EL may also be enhanced, and the short circuit with the counter electrode CE may be suppressed, thereby preventing the vertical leakage current.

FIGS. 9 to 16 are schematic cross-sectional views illustrating a method of manufacturing a display device according to embodiments.

For convenience of illustrations and descriptions, detailed illustrations of the base substrate 100, and structures and elements between the base substrate 100 and the third via insulating layer VIA3 are omitted in FIGS. 9 to 16.

Referring to FIG. 9, as described with reference to FIG. 3, a TFT-array including the transistor structures TR1 and TR2 may be formed on the base substrate 100.

The first via insulation layer VIA1 covering the first and second transistor structures TR1 and TR2 may be formed, and the first via electrode VE1 may be formed to be connected to each of the contact electrodes included in the first and second transistor structures TR1 and TR2 through the first via insulation layer VIA1.

Thereafter, as described with reference to FIG. 3, the second via insulation layer VIA2, the second via electrode VE2, the third via insulation layer VIA3, and the third via electrode VE3 may be sequentially formed.

Preliminary pixel electrodes PPE1 and PPE2 may be formed on the third via insulation layer VIA3 and the third via electrode VE3.

The first conductive layer CL1, a metal layer ML, and the intermediate insulating layer ITL may be sequentially formed on the third via insulation layer VIA3.

As described above, the stacked number of via insulation layers is exemplary, and is not limited as illustrated in FIG. 3. For example, a single-layered or a double-layered via insulation layer may be formed.

As described above, in some embodiments, the first conductive layer CL1 may be formed by a deposition process such as a sputtering process to include titanium (Ti), tantalum (Ta), or a transparent conductive oxide such as ITO. The metal layer ML may be formed by a deposition process such as a sputtering process to include silver (Ag) and/or aluminum (Al). The intermediate insulating layer ITL may be formed by a deposition process such as a CVD process to include an insulating oxide such as silicon oxide.

Thereafter, the intermediate insulating layer ITL, the metal layer ML, and the first conductive layer CL1 may be sequentially etched by a photo-lithography process to form the first preliminary pixel electrode PPE1 and the second preliminary pixel electrode PPE2 separated from each other.

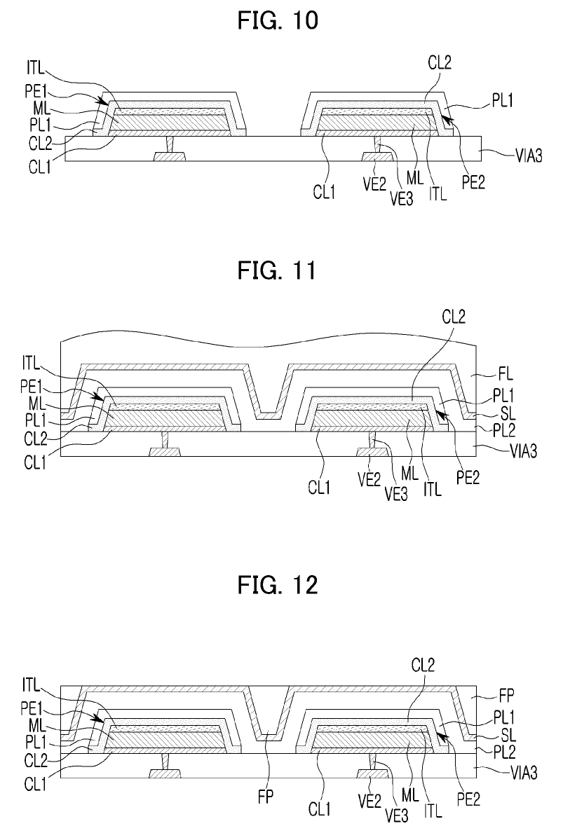

Referring to FIG. 10, the second conductive layer CL2 and the first protective layer PL1 may be sequentially formed on top surfaces of the third via insulation layer VIA3 and the preliminary pixel electrodes PPE1 and PPE2. The second conductive layer CL2 and the first protective layer PL1 may be formed by a deposition process such as a sputtering process or a CVD process to include a transparent conductive oxide such as ITO and silicon oxide, respectively.

Thereafter, portions of the first protective layer PL1 and the second conductive layer CL2 between the neighboring preliminary pixel electrodes PPE1 and PPE2 may be etched by a photo-lithography process. Accordingly, the second conductive layer CL2 and the first protective layer PL1 may be formed to independently cover each of the first preliminary pixel electrode PPE1 and the second preliminary pixel electrodes PPE2.

Thus, the first pixel electrode PE1 and the second pixel electrode PE2 each including the sequential stacked structure of the first conductive layer CL1, the metal layer ML, the intermediate insulating layer ITL and the second conductive layer CL2 may be formed. The second conductive layer CL2 may entirely cover the intermediate insulating layer ITL, the metal layer ML, and the first conductive layer CL1, and may be in contact with a side surface of the metal layer ML. The first protective layer PL1 may entirely cover an upper surface of the second conductive layer CL2.

Referring to FIG. 11, the second protection layer PL2 and the stopper layer SL may be sequentially formed along the top surfaces of the third via insulation layer VIA3 and the first protective layer PL1 to cover the pixel electrodes PE1 and PE2.

The second protective layer PL2 and the stopper layer SL may be formed by a deposition process such as a CVD process to include silicon oxide and silicon nitride, respectively.

Thereafter, a filling layer FL filling a space between the pixel electrodes PE1 and PE2 may be formed on the stopper layer SL. The filling layer FL may be formed by a coating process such as a spin coating process using an organosiloxane material such as TEOS or an organosilane material.

Referring to FIG. 12, an upper portion of the filling layer FL may be removed by a polishing process such as a chemical mechanical polishing (CMP) until a top surface of the stopper layer SL is exposed. Accordingly, the filling layer FL may be separated in each space between the pixel electrodes PE1 and PE2 to form the filling pattern FP.

The stopper layer SL may substantially serve as a polish stopper layer. The filling pattern FP and the top surfaces of the stopper layer SL may be substantially coplanar with each other.

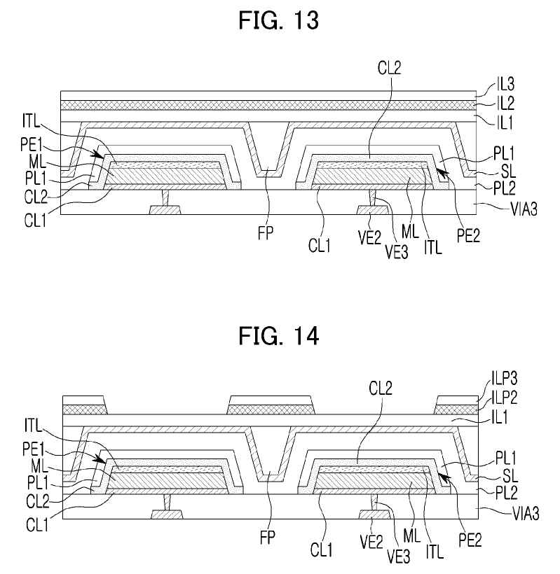

Referring to FIG. 13, a first insulating layer IL1, a second insulating layer IL2, and a third insulating layer IL3 may be sequentially formed on the stopper layer SL and the filling pattern FP. In some embodiments, the first insulating layer IL1, the second insulating layer IL2, and the third insulating layer IL3 may be formed by a deposition process such as a CVD process to include silicon oxide, silicon nitride, and silicon oxide, respectively.

In some embodiments, the first insulating layer IL1 may be substantially merged with the filling pattern FP.

Referring to FIG. 14, the third insulating pattern ILP3 and the second insulating pattern ILP2 may be formed by etching the third insulating layer IL3 and the second insulating layer IL2, respectively.

In some embodiments, the third insulating layer IL3 may be etched to form the third insulating pattern ILP3. For example, the third insulating pattern ILP3 may be formed by a wet etching using an etchant having an etch selectivity for silicon oxide.

Thereafter, the second insulating layer IL2 may be etched to form the second insulating pattern ILP2. For example, the second insulating pattern ILP2 may be formed by a wet etching using an etchant having an etch selectivity for silicon nitride.

In some embodiments, the third insulating layer IL3 and the second insulating layer IL2 may be etched together by a dry etching to form the third insulating pattern ILP3 and the second insulating pattern ILP2.

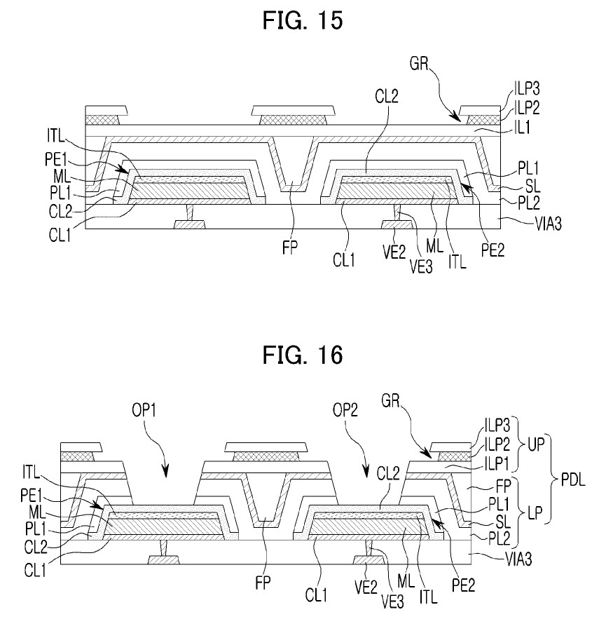

Referring to FIG. 15, the groove GR may be formed by additionally etching the second insulating pattern ILP2 in a horizontal direction.

For example, the second insulating pattern ILP2 may be additionally etched by a wet etching using an etchant such as phosphoric acid having a high etch selectivity for silicon nitride. Accordingly, the second insulating pattern ILP2 may be retreated in the horizontal direction to form the groove GR. A lateral leakage between pixels adjacent to the groove GR may be prevented.

According to embodiments, etching damages to the first insulating layer IL1 or the first insulating pattern ILP1 may be suppressed by adjusting the wet etching condition. Thus, as described above, the thickness deviation of the first insulating pattern ILP1 may be suppressed, and a substantially flat top surface of the first insulating layer IL1 or the first insulating pattern ILP1 may be maintained.

According to embodiments, the second insulating pattern ILP2 may be selectively etched so that an etched thickness (an etched amount in the thickness direction) of the first insulating layer IL1 may be suppressed to 5 nm or less.

In some embodiments, the second insulating pattern ILP2 may be selectively etched under a high temperature condition (e.g., 170 ^{o}C or more, 180 ^{o}C or more, 190 ^{o}C or more, or 200 ^{o}C or more) using a high concentration phosphoric acid solution (e.g., 80% or more, 85% or more, or 90% or more).

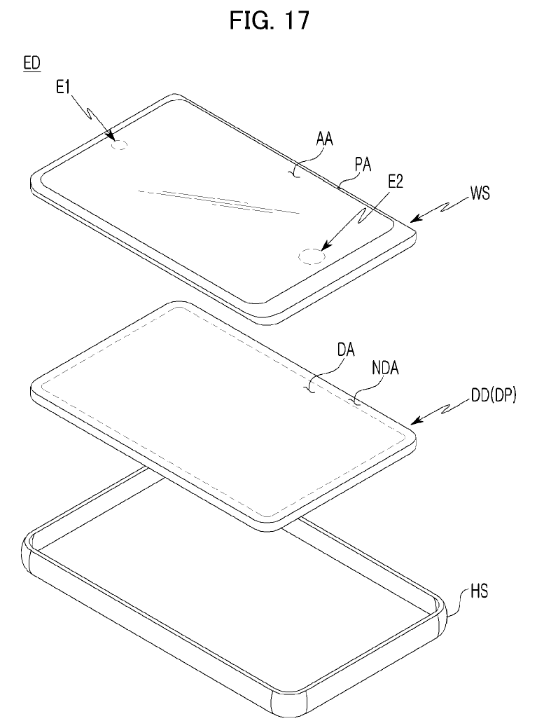

Referring to FIG. 16, the first insulating layer ILP1, the stopper layer SL, the second protective layer PL2, and the first protective layer PL1 may be sequentially etched to form the pixel defining layer PDL. A first opening OP1 and a second opening OP2 exposing top surfaces of the first pixel electrode PE1 and the second pixel electrode PE2, respectively, may be formed by the etching process. A light-emitting region or a pixel region may be substantially defined by the first opening OP1 and the second opening OP2.

The pixel defining layer PDL may include the upper stack UP including the first insulating pattern ILP1, the second insulating pattern ILP2 and the third insulating pattern ILP3, and a lower stack LP including the first protective layer PL1, the second protective layer PL2, the stopper layer SL and the filling pattern FP.

Thereafter, as described with reference to FIG. 3, the light-emitting portion EL, the counter electrode CE, the capping layer CPL, and the encapsulation layer TFE may be sequentially formed on the pixel electrodes PE1 and PE2, and the pixel defining layer PDL.

FIG. 17 is an exploded perspective view of a display device according to embodiments.

According to embodiments, an electronic device ED may be implemented in the form of a mobile phone (smart phone), a tablet, a PC, or the like, including the above-described display device.

Referring to FIG. 17, the electronic device ED may include a window structure WS, a display device DD and a housing HS. The display device DD may include a display panel DP including the transistor structures and the light-emitting element EE as described above. The housing HS, the display device DD and the window structure WS may be sequentially stacked in the third direction.

The window structure WS may provide an external display surface recognized by a user of a display, and may include a transparent material film. For example, the window structure WS may include glass (e.g., ultra-thin glass (UTG)), a hard coating film, a plastic film, or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the display device.

As described with reference to FIG. 1. the display device DD and the display panel DP may have a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In some embodiments, functional device areas E1 and E2 may be included in the active area AA of the window structure WS. For example, a first functional device area E1 may be included at one end portion of the active area AA and may be implemented, e.g., in the form of a camera hole. The second functional device area E2 may serve as a fingerprint sensing area.

For example, a sensor structure for a touch sensing or a fingerprint sensing may be disposed in the display panel DP or between the window structure WS and the display panel DP.

The housing HS may serve as a frame structure or a housing of the display device DD or the electronic device ED. A cover panel may be disposed between the housing HS and the display panel DP. The housing HS or the cover panel may include a plate (e.g., an SUS plate) that supports the display panel DP, the printed circuit board 200 (see FIG. 1), or the like. The housing HS or the cover panel may include an elastic body for absorbing shock of the display device DD.

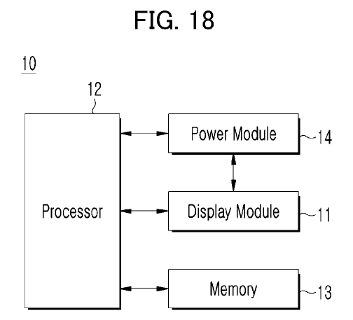

FIG. 18 is a block diagram of an electronic device in accordance with an embodiment.

Referring to FIG. 18, an electronic device 10 according to an embodiment may include a display module 11, a processor 12, a memory 13 and a power module 14.

The processor 12 may include one or more processors and may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal, and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

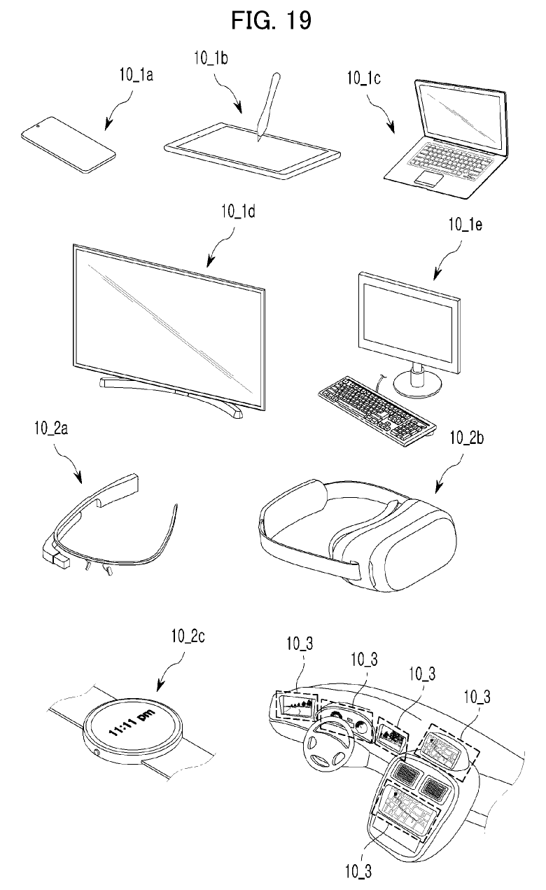

FIG. 19 is a schematic diagram of electronic devices in accordance with various embodiments.

Referring to FIG. 19, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a room mirror display, a head-up display, or the like. The electronic device may include a virtual reality glass or an augmented reality glass.

What is claimed is:

1. A display device, comprising:
a base substrate;
transistor structures arranged on the base substrate;
pixel electrodes electrically connected to each of the transistor structures on the base substrate;
a pixel defining layer comprising:
a lower stack filling a space between the pixel electrodes and covering a peripheral portion of the pixel electrodes; and
an upper stack comprising a first insulating pattern, a second insulating pattern, and a third insulating pattern sequentially stacked on the lower stack; and
a light-emitting portion on the pixel defining layer and the pixel electrodes; and
a counter electrode on the light-emitting portion,
wherein a width of the second insulating pattern is smaller than a width of the first insulating pattern and a width of the third insulating pattern, and a difference between a maximum thickness and a minimum thickness of the first insulating pattern is 5 nm or less.

2. The display device of claim 1, wherein the difference between the maximum thickness and the minimum thickness of the first insulating pattern is 4 nm or less.

3. The display device of claim 1, wherein a thickness of the second insulating pattern is smaller than a thickness of the first insulating pattern and a thickness of the third insulating pattern.

4. The display device of claim 3, wherein the thickness of the first insulating pattern and the thickness of the third insulating pattern is in a range from 180 Å to 250 Å, and the thickness of the second insulating pattern is in a range from 80 Å to 200 Å.

5. The display device of claim 1, wherein the first insulating pattern and the third insulating pattern include silicon oxide, and the second insulating pattern includes silicon nitride.

6. The display device of claim 1, wherein the upper stack has a groove defined by a top surface of the first insulating pattern, a side surface of the second insulating pattern, and a bottom surface of the third insulating pattern.

7. The display device of claim 1, wherein the lower stack comprises a stopper layer and a filling pattern on the stopper layer.

8. The display device of claim 7, wherein the stopper layer includes silicon nitride, and the filling pattern includes a siloxane-based material or silane-based material.

9. The display device of claim 7, wherein a top surface of the stopper layer and a top surface of the filling pattern are located in the same plane.

10. The display device of claim 7, wherein the first insulating pattern and the filling pattern are an integral member.

11. The display device of claim 1, wherein the light-emitting portion comprises a first emission layer, a charge generation layer, and a second emission layer sequentially stacked on the pixel electrode and the pixel defining layer.

12. The display device of claim 11, wherein the first emission layer and the second emission layer are blue emission layers.

13. The display device of claim 1, wherein each of the pixel electrodes comprises a first conductive layer, a metal layer, and a second conductive layer including a transparent conductive oxide which are sequentially stacked from the base substrate.

14. The display device of claim 13, wherein the second conductive layer contacts a side surface of the metal layer.

15. A method of manufacturing a display device, comprising:
forming pixel electrodes on the base substrate;
sequentially forming a first insulating layer, a second insulating layer, and a third insulating layer covering the pixel electrodes;
etching the third insulating layer and the second insulating layer to form a third insulating pattern and a second insulating pattern;
etching a side surface of the second insulating pattern by a wet etching while suppressing an etched thickness of the first insulating layer to 5 nm or less to form a groove;
etching the first insulating layer to form a first insulating pattern;
forming a light-emitting portion on the pixel electrodes; and
forming a counter electrode on the light-emitting portion.

16. The method of claim 15, further comprising, before sequentially forming the first insulating layer, the second insulating layer, and the third insulating layer:
forming a stopper layer covering the pixel electrodes;
forming a filling layer on the stopper layer to fill a space between the pixel electrodes; and
polishing the filling layer so that a top surface of the stopper layer is exposed.

17. The method of claim 16, wherein the first insulating layer, the second insulating layer, and the third insulating layer are sequentially formed on the stopper layer and the filling layer, and
the second insulating layer and the stopper layer are formed of silicon nitride, and the first insulating layer and the third insulating layer are formed of silicon oxide.

18. The method of claim 16, further comprising, before forming the light-emitting portion:
etching the filling layer and the stopper layer to form an opening exposing a top surface of the pixel electrode.

19. An electronic device, comprising:
a display device;
a memory; and
one or more processors executing data included in the memory to control an operation of the display device,
wherein the display device comprises:
a base substrate;
transistor structures arranged on the base substrate;
pixel electrodes electrically connected to each of the transistor structures on the base substrate;
a pixel defining layer comprising:
a lower stack filling a space between the pixel electrodes and covering a peripheral portion of the pixel electrodes; and
an upper stack comprising a first insulating pattern, a second insulating pattern, and a third insulating pattern sequentially stacked on the lower stack; and
a light-emitting portion on the pixel defining layer and the pixel electrodes; and
a counter electrode on the light-emitting portion,
wherein a width of the second insulating pattern is smaller than a width of the first insulating pattern and a width of the third insulating pattern, and a difference between a maximum thickness and a minimum thickness of the first insulating pattern is 5 nm or less.

20. The electronic device of claim 19, wherein the electronic device includes virtual reality or augmented reality glasses, a smartphone, a tablet personal computer (PC), a laptop, a television, a desk monitor, smart glasses, a head-mounted display, a smart watch, or a vehicle display.
